(19) United States
(12) Patent Application Publication
(10) Pub. No.: US 2026/0155188 A1
(43) Pub. Date: Jun. 4, 2026

(54) SEMICONDUCTOR MEMORY DEVICE AND OPERATING METHOD THEREOF

(71) Applicant: SK hynix Inc., Gyeonggi-do (KR)

(72) Inventors: Hae Soo KIM, Gyeonggi-do (KR); Jae Sung SIM, Gyeonggi-do (KR); Hyun Young SHIM, Gyeonggi-do (KR)

(21) Appl. No.: 19/238,551

(22) Filed: Jun. 16, 2025

(30) Foreign Application Priority Data
Dec. 4, 2024 (KR) 10-2024-0178671

(51) Int. Cl. G11C 16/26; G11C 16/04; G11C 16/10; G11C 16/32

(52) U.S. Cl. CPC G11C 16/26; G11C 16/0483; G11C 16/10; G11C 16/32

(57) ABSTRACT

A semiconductor memory device and a method of operating the semiconductor memory device are provided. The semiconductor memory device includes a memory cell array including a plurality of memory blocks; a peripheral circuit performing a program operation or a read operation on a selected memory block from among the plurality of memory blocks; a temperature measurement circuit performing a temperature measurement operation to measure a first temperature during the program operation and a second temperature during the read operation; and a block read counter deriving a read count increment of the selected memory block based on the first temperature and the second temperature and updating a read count value of the selected memory block based on the read count value and the derived read count increment.

### CROSS-REFERENCE TO RELATED APPLICATION

The present application claims priority under 35 U.S.C. § 119(a) to Korean patent application number 10-2024-0178671, filed on Dec. 4, 2024, the entire disclosure of which is incorporated herein by reference.

### BACKGROUND

### 1. Technical Field

Various embodiments of the present disclosure generally relate to an electronic device, and more particularly, to a semiconductor memory device and a method of operating the semiconductor memory device.

### 2. Related Art

A semiconductor memory device is a memory device implemented using semiconductors such as silicon (Si), germanium (Ge), gallium arsenide (GaAs), indium phosphide (InP), or the like. A semiconductor memory device may be broadly classified as a volatile memory device or a nonvolatile memory device.

A volatile memory device loses stored data when power is not supplied. Examples of volatile memory devices include a Static Random-Access Memory (SRAM) device, a Dynamic Random-Access Memory (DRAM) device, and a Synchronous DRAM (SDRAM). A nonvolatile memory device retains stored data even in the absence of supplied power. Examples of nonvolatile memory devices include a Read Only Memory (ROM) device, a Programmable ROM (PROM) device, an Electrically Programmable ROM (EPROM) device, an Electrically Erasable and Programmable ROM (EEPROM) device, a flash memory device, a Phase-change Random-Access Memory (PRAM) device, a Magnetic RAM (MRAM) device, a Resistive RAM (RRAM) device, and a Ferroelectric RAM (FRAM) device. A flash memory device may be broadly classified as a NOR-type memory device or a NAND-type memory device.

### SUMMARY

Various embodiments of the present disclosure are directed to a semiconductor memory device with improved operational reliability and a method of operating the semiconductor memory device.

According to an embodiment of the present disclosure, a semiconductor memory device may include a memory cell array including a plurality of memory blocks; a peripheral circuit performing a program operation or a read operation on a selected memory block from among the plurality of memory blocks; a temperature measurement circuit performing a temperature measurement operation to measure a first temperature during the program operation and a second temperature during the read operation; and a block read counter deriving a read count increment of the selected memory block based on the first temperature and the second temperature and updating a read count value of the selected memory block based on the read count value and the derived read count increment.

According to an embodiment of the present disclosure, a method of operating a semiconductor memory device may include performing a program operation on a selected memory block among a plurality of memory blocks, and measuring a first temperature during the program operation; performing a read operation on the selected memory block, and measuring a second temperature during the read operation; deriving a read count increment of the selected memory block based on the measured first and second temperatures; and updating a read count value of the selected memory block based on the read count value and the read count increment.

According to an embodiment of the present disclosure, a method of operating a semiconductor memory device may include performing a program operation on a selected memory block among a plurality of memory blocks, and measuring a first temperature during the program operation; performing a read operation on the selected memory block, and measuring a second temperature during the read operation; and adjusting a retention limit time of the selected memory block based on the measured first and second temperatures.

### BRIEF DESCRIPTION OF THE DRAWINGS

FIG. 1 is a block diagram illustrating a semiconductor memory device according to an embodiment of the present disclosure;

FIG. 2 is a block diagram illustrating an embodiment of a memory cell array of FIG. 1;

FIG. 3 is a diagram illustrating another embodiment of the memory cell array of FIG. 1;

FIG. 4 is a diagram illustrating another embodiment of the memory cell array of FIG. 1;

FIG. 5 is a diagram illustrating another embodiment of the memory cell array of FIG. 1;

FIG. 6 is a diagram illustrating an embodiment of a block read counter of FIG. 1;

FIG. 7 is a diagram illustrating an embodiment of a retention characteristic determiner of FIG. 1;

FIG. 8 is a flowchart illustrating a method of operating a semiconductor memory device according to an embodiment of the present disclosure;

FIG. 9 is a diagram illustrating the temperature difference between a program operation and a read operation and the number of fail bits in data read during the read operation;

FIG. 10 is a diagram illustrating a method of setting a read count increment based on an internal temperature during a program operation and an internal temperature during a read operation according to an embodiment of the present disclosure;

FIG. 11 is a flowchart illustrating a method of operating a semiconductor memory device according to another embodiment of the present disclosure;

FIG. 12 is a diagram illustrating a method of adjusting a retention limit time of a memory block based on an internal temperature during a program operation and an internal temperature during a read operation according to an embodiment of the present disclosure;

FIG. 13 is a block diagram illustrating a memory system including the semiconductor memory device of FIG. 1;

FIG. 14 is a block diagram illustrating an application example of the memory system of FIG. 13; and

FIG. 15 is a block diagram illustrating a computing system including the memory system described with reference to FIG. 14.

### DETAILED DESCRIPTION

The advantages and features of the present invention, and methods of achieving them will be described with embodiments described in detail with reference to the accompanying drawings. However, the embodiments of the present disclosure are not limited to the embodiments described herein and may be embodied in other forms. Rather, the embodiments are provided to illustrate the present invention in sufficient detail for those skilled in the art to which the present disclosure pertains to be able to readily implement the technical concepts of the present disclosure.

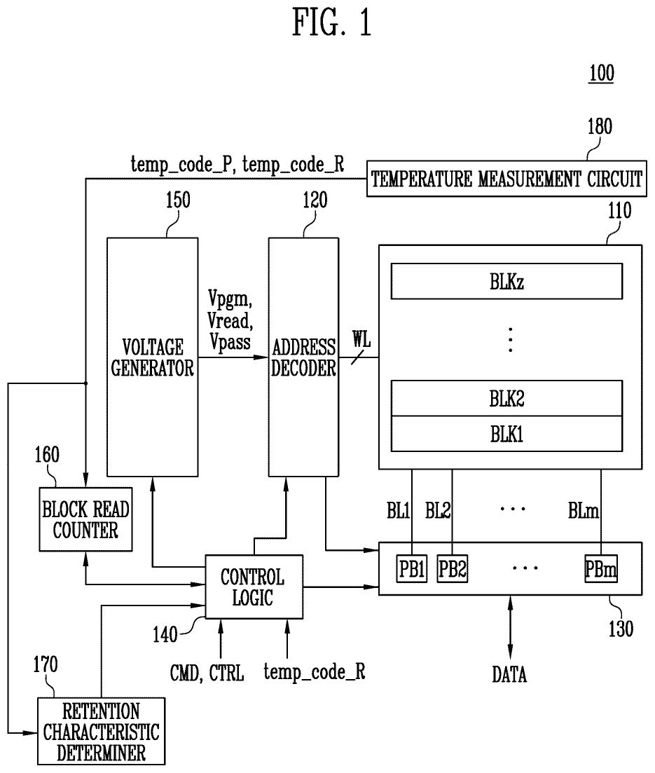

FIG. 1 is a block diagram illustrating a semiconductor memory device 100 according to an embodiment of the present disclosure.

Referring to FIG. 1, the semiconductor memory device 100 includes a memory cell array 110, an address decoder 120, a read and write circuit 130, control logic 140, a voltage generator 150, a block read counter 160, a retention characteristic determiner 170, and a temperature measurement circuit 180.

The memory cell array 110 includes a plurality of memory blocks BLK1 to BLKz. The plurality of memory blocks BLK1 to BLKz are connected to the address decoder 120 via word lines WL. The plurality of memory blocks BLK1 to BLKz are connected to the read and write circuit 130 via bit lines BL1 to BLm. Each of the plurality of memory blocks BLK1 to BLKz includes a plurality of memory cells. In an embodiment, the plurality of memory cells are nonvolatile memory cells, which may have a vertical channel structure. The memory cell array 110 may be a memory cell array with a two-dimensional structure. In an embodiment, the memory cell array 110 may be a memory cell array with a three-dimensional structure.

The plurality of memory cells included in the memory cell array may each store at least two bits of data. In an embodiment, each of the plurality of memory cells included in the memory cell array 110 may be a multi-level cell (MLC) storing two bits of data. In another embodiment, each of the plurality of memory cells included in the memory cell array 110 may be a triple-level cell (TLC) storing three bits of data. In another embodiment, each of the plurality of memory cells included in the memory cell array 110 may be a quad-level cell (QLC) storing four bits of data. According to an embodiment, the memory cell array 110 may include the plurality of memory cells each storing five or more bits of data.

The address decoder 120, the read and write circuit 130, and the voltage generator 150 operate as a peripheral circuit to drive the memory cell array 110. The address decoder 120 is connected to the memory cell array 110 via the word lines WL. The address decoder 120 is configured to operate in response to control of the control logic 140. The address decoder 120 receives addresses through an input/output buffer in the semiconductor memory device 100.

The address decoder 120 is configured to decode a block address among the received addresses. The address decoder 120 selects at least one memory block based on the decoded block address. During a program voltage apply operation of a program operation, the address decoder 120 applies a program voltage Vpgm generated by the voltage generator 150 to a selected word line of the selected memory block, and a pass voltage Vpass to the remaining unselected word lines. During a program verify operation, the address decoder 120 applies a verify voltage generated by the voltage generator 150 to the selected word line of the selected memory block, and applies the pass voltage Vpass to the remaining unselected word lines. During a read operation, the address decoder 120 applies a read voltage Vread generated by the voltage generator 150 to the selected word line of the selected memory block, and applies the pass voltage Vpass to the remaining unselected word lines.

The address decoder 120 is configured to decode a column address among the received addresses. The address decoder 120 transmits the decoded column address to the read and write circuit 130.

A program operation and a read operation of the semiconductor memory device 100 are performed in units of pages. An address received when the program operation and the read operation are requested includes a block address, a row address, and a column address. The address decoder 120 selects one memory block and one word line according to the block address and the row address. The column address is decoded by the address decoder 120 and provided to the read and write circuit 130.

The address decoder 120 may include a block decoder, a row decoder, a column decoder, an address buffer, and the like.

The read and write circuit 130 includes a plurality of page buffers PB1 to PBm. The read and write circuit 130 may operate as a “write circuit” during a program operation of the memory cell array 110 and as a “read circuit” during a read operation of the memory cell array 110. The plurality of page buffers PB1 to PBm are connected to the memory cell array 110 via the bit lines BL1 to BLm, respectively. The plurality of page buffers PB1 to PBm may receive and temporarily store data DATA during the program operation, and may apply a program permission voltage (e.g., a ground voltage) or a program inhibition voltage (e.g., a power voltage) to the bit lines BL1 to BLm based on the temporarily stored data DATA during a program voltage apply operation of the program operation. During the read operation and a program verify operation, the plurality of page buffers PB1 to PBm continuously supply a sensing current to bit lines connected to memory cells in order to sense a threshold voltage of the memory cells, sense through a sense node that the amount of current flowing changes depending on a program state of a corresponding memory cell, and latch the change as sense data. The read and write circuit 130 operates in response to page buffer control signals output from the control logic 140.

During the read operation, the read and write circuit 130 senses data in the memory cell, temporarily stores the read data, and outputs the data DATA to the input and output buffer of the semiconductor memory device 100. In an embodiment, the read and write circuit 130 may include a column select circuit or the like in addition to page buffers (or page registers).

The control logic 140 may be connected to the address decoder 120, the read and write circuit 130, and the voltage generator 150. The control logic 140 receives a command CMD and a control signal CTRL through the input/output buffer of the semiconductor memory device 100. The control logic 140 is configured to control various operations of the semiconductor memory device 100 in response to the control signal CTRL. The control logic 140 may control the address decoder 120, the read and write circuit 130, and the voltage generator 150 to perform a program operation or a read operation of the memory cell array 110. The control logic 140 may receive a read operation temperature code temp_code_R corresponding to an internal temperature of the semiconductor memory device 100 from the temperature measurement circuit 180 during the read operation. Further, the control logic 140 may set a level of the pass voltage Vpass used during the read operation based on the received read operation temperature code temp_code_R, and control the voltage generator 150 to generate the pass voltage Vpass of the set level. For example, the control logic 140 may set the level of the pass voltage Vpass to be relatively high when the internal temperature during the read operation is relatively low. In general, when performing the read operation, the amount of cell current flowing through the memory cell in an environment with a relatively low internal temperature may be reduced compared to an environment with a relatively high internal temperature. Therefore, in an embodiment of the present disclosure, the control logic 140 may compensate for the amount of cell current flowing in the memory cell by setting the level of the pass voltage Vpass to be higher when the internal temperature of the semiconductor memory device 100 during the read operation is relatively low.

The control logic 140 may control a read reclaim operation of each memory block based on a read count value of each of the plurality of memory blocks BLK1 to BLKz which is stored in the block read counter 160. To prevent or mitigate read failures from occurring in a corresponding memory block due to repeated read operations for the corresponding memory block, an operation of reading data of the corresponding memory block and storing the read data in a new memory block may be performed, which is referred to as read reclaiming. For example, the control logic 140 may control the peripheral circuit, such as the address decoder 120, the read and write circuit 130, and the voltage generator 150, to perform the read reclaim operation on a memory block of which a read count value exceeds a set value.

When the control logic 140 receives a read reclaim request signal corresponding to at least one of the memory blocks from the retention characteristic determiner 170, the control logic 140 may control, for example, the address decoder 120, the read and write circuit 130, and the voltage generator 150 to perform a read reclaim operation on a corresponding memory block.

During a read operation, the voltage generator 150 generates the read voltage Vread and the pass voltage Vpass in response to a voltage generator control signal output from the control logic 140. The voltage generator 150 may generate an adjusted pass voltage Vpass by adjusting the level of the pass voltage Vpass in response to the control of the control logic 140 during the read operation.

The block read counter 160 counts and stores the number of times each of the plurality of memory blocks BLK1 to BLKz in the memory cell array 110 is read. The number of times each memory block is read may be referred to as a “read count value”. For example, the read count value for each memory block is reset when a corresponding memory block is erased or programmed, and each time a read operation is performed on the corresponding memory block, the read count value is increased by 1. The read count value that is increased each time the read operation is performed may be referred to as a “read count increment.”

The block read counter 160 may receive a program operation temperature code temp_code_P corresponding to an internal temperature of the semiconductor memory device 100 during a program operation and the read operation temperature code temp_code_R corresponding to an internal temperature of the semiconductor memory device 100 during a read operation measured by the temperature measurement circuit 180. Further, the block read counter 160 may adjust an increment of the read count value based on the received program operation temperature code temp_code_P and the received read operation temperature code temp_code_R. For example, the block read counter 160 may receive and store the program operation temperature code temp_code_P during the program operation, and may adjust the increment of the read count value based on the read operation temperature code temp_code_R received during the read operation and the previously stored program operation temperature code temp_code_P. For example, the block read counter 160 may adjust the increment of the read count value based on the internal temperature during the program operation corresponding to the program operation temperature code temp_code_P and the internal temperature during the read operation corresponding to the read operation temperature code temp_code_R. For example, the block read counter 160 may adjust the increment of the read count value based on the temperature difference between the internal temperature during the program operation corresponding to the program operation temperature code temp_code_P and the internal temperature during the read operation corresponding to the read operation temperature code temp_code_R and the internal temperature during the read operation. For example, the block read counter 160 may increase the read count increment to a value greater than a default value (e.g., 1) when the temperature difference between the program operation and the read operation is relatively large, and increase the read count increment to a value greater than the default value when the internal temperature during the read operation is relatively low.

When the command CMD corresponding to the read operation is received, the control logic 140 may set the read voltage Vread and the pass voltage Vpass to be used during the read operation based on the read operation temperature code temp_code_R corresponding to the internal temperature of the semiconductor memory device 100 measured by the temperature measurement circuit 180 and a read count value of the memory block to perform the read operation which is stored in the block read counter 160. Further, the control logic 140 may control the voltage generator 150 to generate the set read voltage Vread and pass voltage Vpass.

The retention characteristic determiner 170 may manage a retention limit time for each of the plurality of memory blocks BLK1 to BLKz in the memory cell array 110, and may measure an elapsed time after a program operation on a memory block on which the program operation has been performed among the plurality of memory blocks BLK1 to BLKz. The retention characteristic determiner 170 may detect a memory block of which a measured elapsed time has reached the retention limit time, and output a control signal to the control logic 140 to perform a read reclaim operation on the detected memory block.

The retention characteristic determiner 170 may receive and store the program operation temperature code temp_code_P corresponding to the internal temperature of the semiconductor memory device 100 during the program operation which is measured by the temperature measurement circuit 180, and may receive the read operation temperature code temp_code_R corresponding to the internal temperature of the semiconductor memory device 100 during the read operation. Further, the retention characteristic determiner 170 may maintain or shorten the retention limit time of each of the memory blocks on which the program operation is performed among the plurality of memory blocks BLK1 to BLKz, based on the previously stored program operation temperature code temp_code_P and the received read operation temperature code temp_code_R. For example, the retention characteristic determiner 170 may adjust the retention limit time of a corresponding memory block on which the program operation is performed among the plurality of memory blocks BLK1 to BLKz based on the internal temperature during the program operation on the corresponding memory block and the internal temperature during the read operation on the corresponding memory block each time the read operation is performed on the corresponding memory block. For example, the retention characteristic determiner 170 may manage the retention limit time of the corresponding memory block by decreasing the retention limit time of the corresponding memory block as the temperature difference between the program operation and the read operation in the corresponding memory block is relatively large, and decreasing the retention limit time of the corresponding memory block as the internal temperature during the read operation of the corresponding memory block is relatively low.

Although FIG. 1 illustrates the block read counter 160 and the retention characteristic determiner 170 as components implemented separately from the control logic 140, the block read counter 160 and the retention characteristic determiner 170 may be implemented to be included in the control logic 140.

The temperature measurement circuit 180 may measure the internal temperature of the semiconductor memory device 100 during the program operation of the selected memory block, and generate and output the program operation temperature code temp_code_P corresponding to the measured internal temperature. The temperature measurement circuit 180 may measure the internal temperature of the semiconductor memory device 100 during the read operation of a selected memory block, and generate and output the read operation temperature code temp_code_R corresponding to the measured internal temperature. The temperature measurement circuit 180 may be arranged physically adjacent to the memory cell array 110.

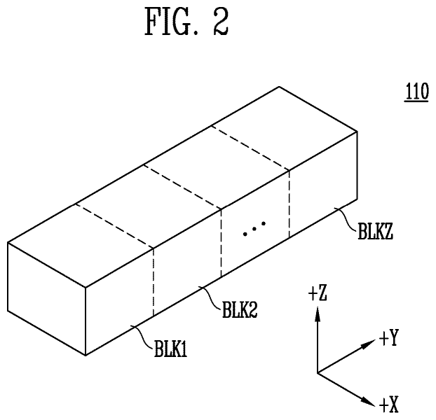

FIG. 2 is a block diagram illustrating an embodiment of the memory cell array 110 of FIG. 1.

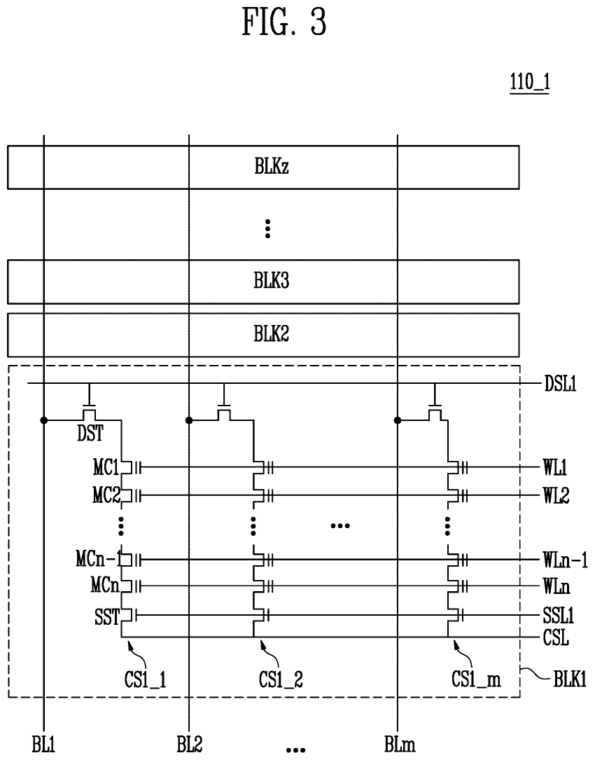

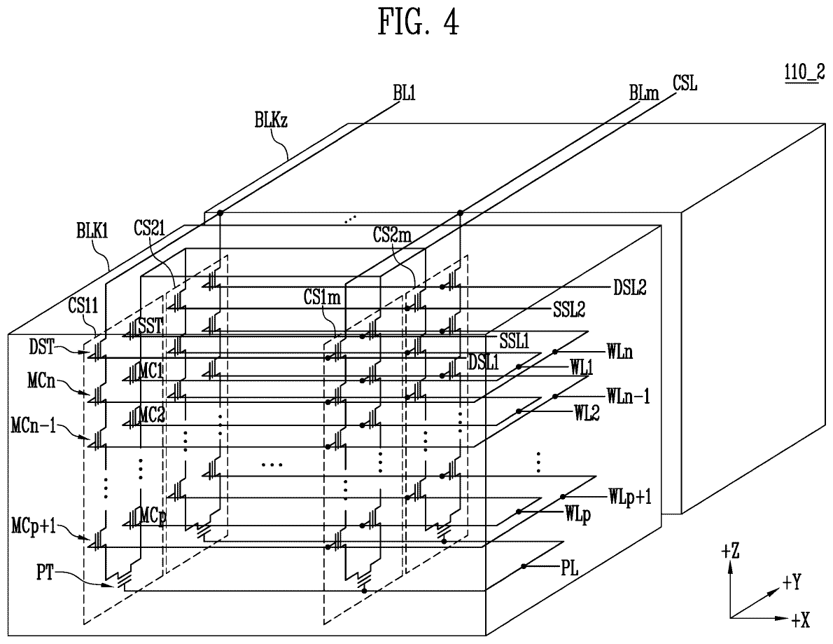

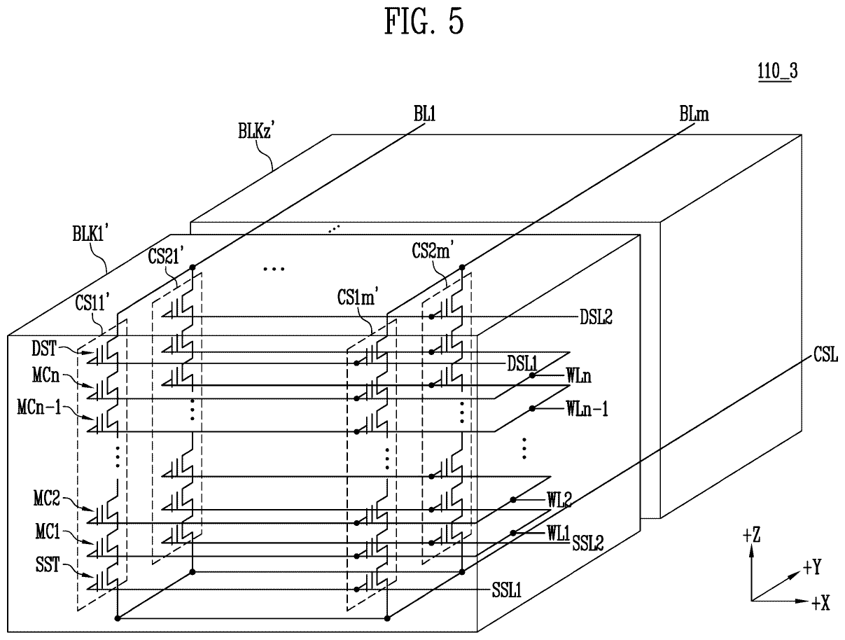

Referring to FIG. 2, the memory cell array 110 includes the plurality of memory blocks BLK1 to BLKz. Each memory block may have a three-dimensional structure. Each memory block includes a plurality of memory cells stacked over a substrate. The plurality of memory cells are arranged in a +X direction, a +Y direction, and a +Z direction. The structure of each memory block, which is formed in a three-dimensional structure, will be described in more detail with reference to FIGS. 4 and 5. However, unlike an embodiment shown in FIG. 2, each memory block of the memory cell array 110 may also have a two-dimensional structure. A memory block with a two-dimensional structure will be described in more detail with reference to FIG. 3.

FIG. 3 is a diagram illustrating another embodiment 110_1 of the memory cell array 110 of FIG. 1.

Referring to FIG. 3, the first to zth memory blocks BLK1 to BLKz included in the memory cell array 110_1 are connected in common to the first to mth bit lines BL1 to BLm. In FIG. 3, elements included in the first memory block BLK1 of the plurality of memory blocks BLK1 to BLKz are shown, and elements included in each of the remaining memory blocks BLK2 to BLKz are omitted. It will be understood that each of the remaining memory blocks BLK2 through BLKz is configured similarly to the first memory block BLK1.

The memory block BLK1 includes a plurality of cell strings CS1_1 to CS1_m. The first to mth cell strings CS1_1 to CS1_m are connected to the first to mth bit lines BL1 to BLm, respectively.

Each of the first to mth cell strings CS1_1 to CS1_m includes a drain select transistor DST, a plurality of memory cells MC1 to MCn connected in series, and a source select transistor SST. The drain select transistor DST is connected to a drain select line DSL1. First to nth memory cells MC1 to MCn are connected to first to nth word lines WL1 to WLn, respectively. The source select transistor SST is connected to a source select line SSL1. The drain side of the drain select transistor DST is connected to a corresponding bit line. The drain select transistors of the first to mth cell strings CS1_1 to CS1_m are connected to the first to mth bit lines BL1 to BLm, respectively. The source side of the source select transistor SST is connected to a common source line CSL. In an embodiment, the common source line CSL may be connected in common to the first to zth memory blocks BLK1 to BLKz.

The drain select line DSL1, the first to nth word lines WL1 to WLn, and the source select line SSL1 are controlled by the address decoder 120. The common source line CSL is controlled by the control logic 140. The first to mth bit lines BL1 to BLm are controlled by the read and write circuit 130.

As shown in FIG. 3, the memory cell array 110 of the semiconductor memory device 100 according to an embodiment of the present disclosure may be configured as the memory cell array 110_1 with a two-dimensional structure. However, according to an embodiment, the memory cell array 110 of the semiconductor memory device 100 may also be configured as a memory cell array with a three-dimensional structure. The memory cell array with a three-dimensional structure will be described later with reference to FIGS. 4 and 5.

FIG. 4 is a diagram illustrating another embodiment 110_2 of the memory cell array 110 of FIG. 1.

Referring to FIG. 4, the memory cell array 110_2 includes the plurality of memory blocks BLK1 to BLKz. In FIG. 4, the internal configuration of the first memory block BLK1 is shown, and the internal configurations of the remaining memory blocks BLK2 to BLKz are omitted. It will be understood that the second to zth memory blocks BLK2 to BLKz are configured similarly to the first memory block BLK1.

The first memory block BLK1 includes a plurality of cell strings CS11 to CS1m and CS21 to CS2m. In an embodiment, each of the plurality of cell strings CS11 to CS1m and CS21 to CS2m may be formed in a ‘U’ shape. In the first memory block BLK1, m cell strings are arranged in the row direction (i.e., the +X direction). FIG. 4 illustrates that two cell strings are arranged in the column direction (i.e., the +Y direction). However, the embodiment shown in FIG. 4 is for illustrative purposes only and it will be understood that three or more cell strings may be arranged in the column direction.

Each of the plurality of cell strings CS11 to CS1m and CS21 to CS2m includes at least one source select transistor SST, the first to nth memory cells MC1 to MCn, a pipe transistor PT, and at least one drain select transistor DST.

The select transistors SST and DST, and the memory cells MC1 to MCn may have a similar structure to each other. In an embodiment, each of the select transistors SST and DST, and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, or the blocking insulating layer may be provided in each cell string.

The source select transistor SST of each cell string is connected between the common source line CSL and each of memory cells MC1 to MCp.

In an embodiment, source select transistors of cell strings arranged in the same row are connected to a source select line which extends in the row direction, and source select transistors of cell strings arranged in different rows are connected to different source select lines. In FIG. 4, the source select transistors of the cell strings CS11 to CS1m in the first row are connected to the first source select line SSL1. The source select transistors of the second row of the cell strings CS21 to CS2m are connected to a second source select line SSL2.

In another embodiment, the source select transistors of the cell strings CS11 to CS1m and CS21 to CS2m may be connected in common to one source select line.

The first to nth memory cells MC1 to MCn of each cell string are connected between the source select transistor SST and the drain select transistor DST.

The first to nth memory cells MC1 to MCn may be divided into first to pth memory cells MC1 to MCp and (p+1)th to nth memory cells MCp+1 to MCn. The first to pth memory cells MC1 to MCp are arranged sequentially in a direction opposite to the +Z direction and are connected in series between the source select transistor SST and the pipe transistor PT. The (p+1)th to nth memory cells MCp+1 to MCn are arranged sequentially in the +Z direction and are connected in series between the pipe transistor PT and the drain select transistor DST. The first to pth memory cells MC1 to MCp and the (p+1)th to nth memory cells MCp+1 to MCn are connected via the pipe transistor PT. Gates of the first to nth memory cells MC1 to MCn of each cell string are connected to the first to nth word lines WL1 to WLn, respectively.

A gate of the pipe transistor PT of each cell string is connected to a pipe line PL.

The drain select transistor DST of each cell string is connected between a corresponding bit line and the memory cells MCp+1 to MCn. The cell strings arranged in the row direction are connected to a drain select line that extends in the row direction. The drain select transistors of the cell strings CS11 to CS1m of the first row are connected to the first drain select line DSL1. The drain select transistors of the cell strings CS21 to CS2m of the second row are connected to a second drain select line DSL2.

The cell strings arranged in the column direction are connected to a bit line that extends in the column direction. In FIG. 4, the cell strings CS11 and CS21 of the first column are connected to the first bit line BL1. The cell strings CS1m and CS2m of the mth column are connected to the mth bit line BLm.

In the cell strings arranged in the row direction, memory cells that are connected to the same word line constitute a page. For example, the memory cells connected to the first word line WL1 of the cell strings CS11 to CS1m in the first row constitute one page. The memory cells connected to the first word line WL1 of the cell strings CS21 to CS2m in the second row constitute another page. The cell strings arranged in a single row direction are selected by selecting one of the drain select lines DSL1 and DSL2. When one of the word lines WL1 to WLn is selected, one page of the selected cell strings is selected.

FIG. 5 is a diagram illustrating another embodiment 110_3 of the memory cell array 110 of FIG. 1.

Referring to FIG. 5, the memory cell array 110_3 includes a plurality of memory blocks BLK1′ to BLKz′. In FIG. 5, the internal configuration of the first memory block BLK1′ is shown, and the internal configurations of the remaining memory blocks BLK2′ to BLKz′ are omitted. It will be understood that the second to zth memory blocks BLK2′ to BLKz′ are configured similarly to the first memory block BLK1′.

The first memory block BLK1′ includes a plurality of cell strings CS11′ to CS1m′ and CS21′ to CS2m′. Each of the plurality of cell strings CS11′ to CS1m′ and CS21′ to CS2m′ extends in the +Z direction. In the first memory block BLK1′, m cell strings are arranged in the +X direction. FIG. 5 illustrates that two cell strings are arranged in the +Y direction. However, the embodiment shown in FIG. 5 is for illustrative purposes only and it will be understood that three or more cell strings may be arranged in the column direction.

Each of the plurality of cell strings CS11′ to CS1m′ and CS21′ to CS2m′ includes at least one source select transistor SST, the first through nth memory cells MC1 to MCn, and at least one drain select transistor DST.

The source select transistor SST of each cell string is connected between the common source line CSL and the memory cells MC1 to MCn. The source select transistors of cell strings arranged in the same row are connected to the same source select line. The source select transistors of the cell strings CS11′ to CS1m′ arranged in the first row are connected to the first source select line SSL1. Source select transistors of the cell strings CS21′ to CS2m′ arranged in the second row are connected to the second source select line SSL2. In another embodiment, the source select transistors of the cell strings CS11′ to CS1m′ and CS21′ to CS2m′ may be connected in common to one source select line.

The first to nth memory cells MC1 to MCn of each cell string are connected in series between the source select transistor SST and the drain select transistor DST. The gates of the first to nth memory cells MC1 to MCn are connected to the first to nth word lines WL1 to WLn, respectively.

The drain select transistor DST of each cell string is connected between a corresponding bit line and the memory cells MC1 to MCn. The drain select transistors of the cell strings arranged in the row direction are connected to the drain select line that extends in the row direction. The drain select transistors of the cell strings CS11′ to CS1m′ of the first row are connected to the first drain select line DSL1. The drain select transistors of the cell strings CS21′ to CS2m′ of the second row are connected to the second drain select line DSL2.

As a result, the memory block BLK1′ of FIG. 5 has an equivalent circuit similar to the memory block BLK1 of FIG. 4, except that the pipe transistor PT in each cell string is excluded from the memory block BLK1′ of FIG. 5.

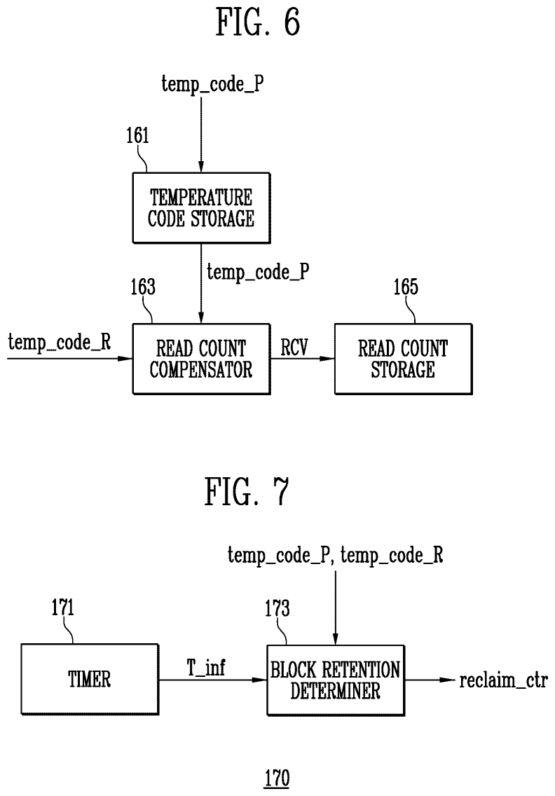

FIG. 6 is a diagram illustrating an embodiment of the block read counter 160 of FIG. 1.

Referring to FIG. 6, the block read counter 160 may include temperature code storage 161, a read count compensator 163, and read count storage 165.

The temperature code storage 161 may receive and store the program operation temperature code temp_code_P from the temperature measurement circuit 180 of FIG. 1. For example, the temperature code storage 161 may receive the program operation temperature code temp_code_P corresponding to an internal temperature of the semiconductor memory device 100 measured during the program operation of a selected memory block among the plurality of memory blocks BLK1 to BLKz of FIG. 1 and store the received program operation temperature code temp_code_P as the program operation temperature code temp_code_P of the selected memory block. Further, the temperature code storage 161 may output, to the read count compensator 163, the program operation temperature code temp_code_P corresponding to the selected memory block which is previously stored during the read operation of the selected memory block.

The read count compensator 163 may adjust and generate a read count increment RCV of the selected memory block based on the read operation temperature code temp_code_R received from the temperature measurement circuit 180 of FIG. 1 during the read operation of the selected memory block and the program operation temperature code temp_code_P corresponding to the selected memory block received from the temperature code storage 161. The read count increment RCV is an increment of a read count value of the selected memory block when one read operation is performed on the selected memory block.

For example, the read count compensator 163 may adjust the increment of the read count value based on the temperature difference between the internal temperature during the program operation corresponding to the program operation temperature code temp_code_P and the internal temperature during the read operation corresponding to the read operation temperature code temp_code_R, and the internal temperature during the read operation. For example, the block read counter 160 may increase the read count increment to a value greater than the default value (e.g., 1) when the temperature difference between the program operation and the read operation is relatively large, and increase the read count increment to a value greater than the default value when the internal temperature during the read operation is relatively low.

The read count storage 165 stores a read count value for each of the plurality of memory blocks BLK1 to BLKz included in the memory cell array 110 of FIG. 1. The read count storage 165 receives the read count increment RCV from the read count compensator 163 and updates the read count value of the selected memory block on which the read operation is performed, based on the received read count increment RCV. The read count value corresponding to each of the memory blocks which is stored in the read count storage 165 may be stored in at least one memory block designated as a system block or a cam block among the plurality of memory blocks BLK1 to BLKz at a certain time or at every idle time. In a power-on operation of the semiconductor memory device, the read count value of each of the plurality of memory blocks BLK1 to BLKz which is stored in the system block or the cam block may be read and stored in the read count storage 165.

FIG. 7 is a diagram illustrating an embodiment of the retention characteristic determiner 170 of FIG. 1.

Referring to FIG. 7, the retention characteristic determiner 170 may include a timer 171 and a block retention determiner 173.

The timer 171 may measure the elapsed time after the program operation on each of the memory blocks on which the program operation is performed among the plurality of memory blocks BLK1 to BLKz in the memory cell array 110 of FIG. 1. Further, the timer 171 may generate and output time information T_inf based the measured elapsed time.

The block retention determiner 173 may manage the retention limit time of each of the plurality of memory blocks BLK1 to BLKz in the memory cell array 110. The block retention determiner 173 may receive the time information T_inf from the timer 171 for each of the memory blocks on which the program operation is performed, and may detect a memory block which has reached the retention limit time based on the time information T_inf. When a memory block that has reached the retention limit time is detected, the block retention determiner 173 may output a read reclaim control signal reclaim_ctr to the control logic 140 of FIG. 1 to perform a read reclaim operation on the memory block.

Further, the block retention determiner 173 may receive the program operation temperature code temp_code_P corresponding to an internal temperature of the semiconductor memory device 100 which is measured by the temperature measurement circuit 180 during the program operation and the read operation temperature code temp_code_R corresponding to an internal temperature of the semiconductor memory device 100 during the read operation which is measured by the temperature measurement circuit 180 during the read operation of a memory block selected from the plurality of memory blocks BLK1 to BLKz in FIG. 1. The block retention determiner 173 may receive and store the program operation temperature code temp_code_P. The block retention determiner 173 may receive the read operation temperature code temp_code_R during the read operation of the selected memory block, and may maintain or shorten the retention limit time of the selected memory block based on the previously stored program operation temperature code temp_code_P corresponding to the selected memory block and the received read operation temperature code temp_code_R corresponding to the selected memory block.

For example, the block retention determiner 173 may adjust the retention limit time of a corresponding memory block on which the program operation is performed among the plurality of memory blocks BLK1 to BLKz based on an internal temperature during the program operation of the corresponding memory block and an internal temperature during the read operation of the corresponding memory block each time the read operation is performed on the corresponding memory block. For example, the block retention determiner 173 may manage the retention limit time of the corresponding memory block by decreasing the retention limit time of the corresponding memory block when the temperature difference between the program operation and the read operation of the corresponding memory block is relatively large, and decreasing the retention limit time of the corresponding memory block when the internal temperature during the read operation of the corresponding memory block is relatively low.

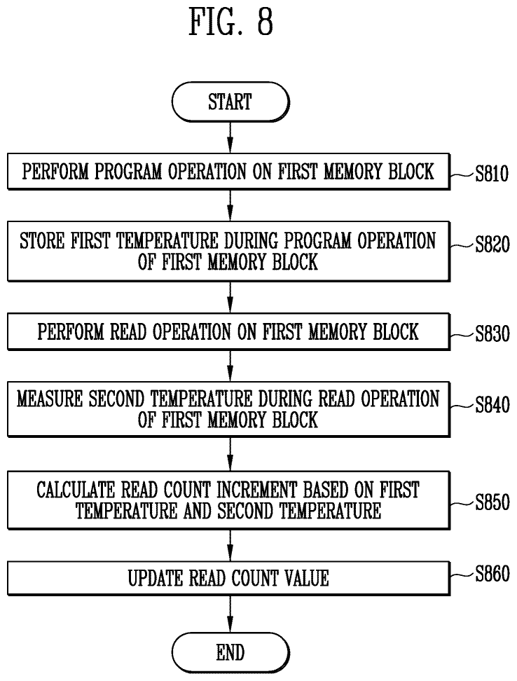

FIG. 8 is a flowchart illustrating a method of operating a semiconductor memory device according to an embodiment of the present disclosure. The method may be performed by elements of the semiconductor memory device 100 shown in FIGS. 1 to 7.

Referring to FIGS. 1 to 8, a method of operating a semiconductor memory device according to an embodiment of the present disclosure will be described as follows.

At S810, the semiconductor memory device 100 performs a program operation on a selected memory block, such as the first memory block BLK1. For example, the semiconductor memory device 100 may receive from an external device a program command CMD corresponding to the first memory block BLK1 and the data DATA to be programmed. The semiconductor memory device 100 may receive from the external device an address corresponding to the first memory block BLK1 together with the program command CMD and the data DATA. The semiconductor memory device 100 may perform the program operation in accordance with the program command CMD to store the data DATA in the first memory block BLK1.

The temperature measurement circuit 180 may measure an internal temperature of the semiconductor memory device 100 during the program operation on the first memory block BLK1.

At S820, the temperature measurement circuit 180 may generate and output the program operation temperature code temp_code_P corresponding to the internal temperature of the semiconductor memory device 100 measured during the program operation on the first memory block BLK1, that is, a first temperature, and the temperature code storage 161 of the block read counter 160 may receive and store the program operation temperature code temp_code_P. That is, the temperature code storage 161 may store the first temperature, which is the internal temperature of the semiconductor memory device 100 during the program operation of the first memory block BLK1.

At S830, the semiconductor memory device 100 performs a read operation on the first memory block BLK1. For example, the semiconductor memory device 100 may receive from the external device a read command CMD corresponding to the first memory block BLK1 and an address corresponding to the first memory block BLK1. The semiconductor memory device 100 may perform the read operation on the first memory block BLK1 in accordance with the read command CMD.

At S840, the temperature measurement circuit 180 may measure an internal temperature of the semiconductor memory device 100 during the read operation on the first memory block BLK1, that is, a second temperature. For example, the temperature measurement circuit 180 may generate and output the read operation temperature code temp_code_R corresponding to the internal temperature of the semiconductor memory device 100 measured during the read operation on the first memory block BLK1, that is, the second temperature.

At S850, the block read counter 160 calculates a read count increment based on the first temperature and the second temperature.

For example, the program operation temperature code temp_code_P corresponding to the first memory block BLK1 may be output to the read count compensator 163. The read count compensator 163 may calculate the read count increment RCV of the first memory block BLK1 based on the program operation temperature code temp_code_P and the read operation temperature code temp_code_R received from the temperature measurement circuit 180. For example, the read count compensator 163 may calculate the temperature difference between the first temperature corresponding to the program operation temperature code temp_code_P and the second temperature corresponding to the read operation temperature code temp_code_R. The read count compensator 163 may set a weight based on the calculated temperature difference and the second temperature. When one read operation is performed on the first memory block BLK1, the read count compensator 163 may calculate the read count increment RCV by multiplying the default value (i.e., 1) by the weight. When N times, where N is an integer greater than or equal to 1, of read operations are performed successively on the first memory block BLK1, the read count compensator 163 may calculate the read count increment RCV by multiplying the default value (i.e., N) by a set weight. For example, the read count compensator 163 may set a weight such that the weight increases when the calculated temperature difference is relatively large, and the weight increases when the second temperature is relatively low. The weight may be a value greater than one. A method of setting the weight will be described in more detail below with reference to FIG. 10.

At S860, the read count storage 165 updates a read count value of the first memory block BLK1 based on the read count increment RCV calculated at S850 above, i.e., updates the read count value of the first memory block BLK1 by adding an existing read count value of the first memory block BLK1 to the calculated read count increment. The updated read count value of the first memory block BLK1 may be referenced during a new read operation of the first memory block. For example, the control logic 140 may set the read voltage Vread based on the internal temperature of the semiconductor memory device 100 and the updated read count value of the first memory block BLK1 during the new read operation.

The control logic 140 may control the peripheral circuit, namely the address decoder 120, the read and write circuit 130, and the voltage generator 150, to perform a read reclaim operation based on a read count value of each of the plurality of memory blocks BLK1 to BLKz. For example, the control logic 140 may control the address decoder 120, the read and write circuit 130, and the voltage generator 150 to perform the read reclaim operation on a memory block of which a read count value exceeds a set number among the plurality of memory blocks BLK1 to BLKz.

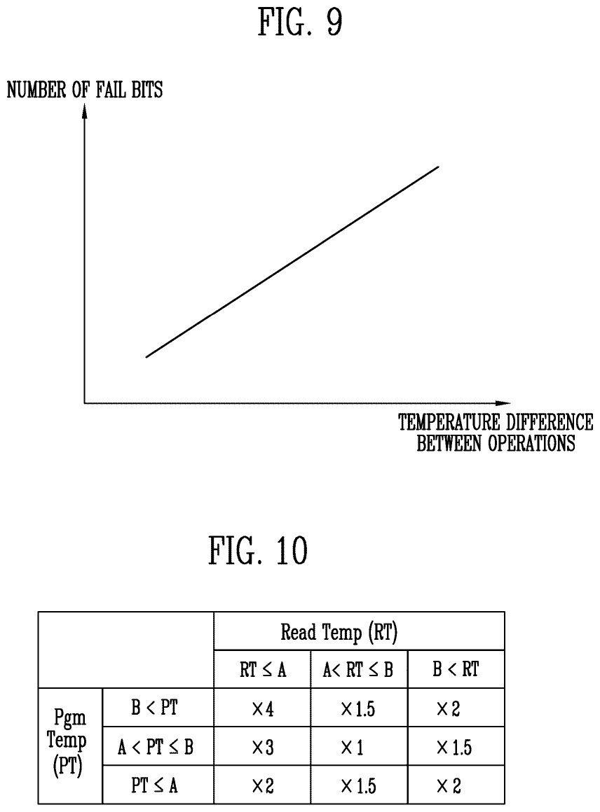

FIG. 9 is a diagram illustrating the temperature difference between a program operation and a read operation and the number of fail bits in data read during the read operation.

When an internal temperature of a semiconductor memory device is relatively low during the read operation, the pass voltage Vpass used during the read operation is set to a relatively high level to perform the read operation. As a result, a memory block on which the read operation is performed is subjected to increased read stress due to the relatively high level of pass voltage Vpass, which may accelerate the deterioration of the memory block.

When the internal temperature of the semiconductor memory device is relatively high during the program operation, a threshold voltage of some memory cells may increase due to heat, resulting in a wide threshold voltage distribution of memory cells, which may reduce a read margin during a subsequent read operation.

When a relatively large difference in the internal temperature of the semiconductor memory device 100 between the program operation and the read operation occurs, the read margin may decrease during the read operation, resulting in an increase in the number of fail bits in the read data.

In general, when performing a read operation, the rate of increase of a cell current flowing in the memory cell is reduced in a relatively low temperature environment. Therefore, even when the memory cell is programmed with a sufficient read margin during a program operation, performing the read operation at a temperature less than a temperature during the program operation may cause a threshold voltage of the memory cell to increase, allowing it to be read. Conversely, when the read operation is performed at a temperature greater than the temperature during the program operation, the threshold voltage of the memory cell may decrease, allowing it to be read. As described above, when the temperature difference between the program operation and the read operation is relatively large, the read margin may decrease during the read operation. Accordingly, as the temperature difference between the program operation and the read operation increases, the number of fail bits included in the data read during the read operation may increase.

FIG. 10 is a diagram illustrating a method of setting a read count increment based on an internal temperature during a program operation and an internal temperature during a read operation according to an embodiment of the present disclosure.

A semiconductor memory device may perform the read operation using a relatively high pass voltage to compensate for the amount of a cell current flowing in a memory cell in an environment with a relatively low internal temperature, which may accelerate the deterioration of a memory block. Also, when the temperature difference between an internal temperature during the program operation and an internal temperature during the read operation is relatively large, as shown in FIG. 9, a read margin during the read operation may be reduced, which may increase the number of fail bits included in the data read during the read operation.

To compensate for the increase in the number of fail bits, in an embodiment of the present disclosure, a weight of the read count increment may be set such that the weight of the read count increment increases when the read operation temperature is relatively low, and the weight of the read count increment increases when the temperature difference between the program operation and the read operation is relatively large.

Referring to FIG. 10, the weight may increase when an internal temperature (i.e., Read Temp; RT) measured during the read operation is relatively low, and the weight may increase when the difference between an internal temperature (i.e., Pgm Temp; PT) measured during the program operation and the internal temperature RT measured during the read operation increases.

For example, when the internal temperature RT measured during the read operation and the internal temperature PT measured during the program operation both fall within a set temperature range, i.e., a temperature range which is greater than a first set temperature A and is less than or equal to a second set temperature B (A<RT≤B, A<PT≤B), the weight may be set to 1.

When the internal temperature RT measured during the read operation is within the set temperature range (A<RT≤B), and the internal temperature PT measured during the program operation is greater than the second set temperature B (B<PT) or is less than or equal to the first set temperature A (PT≤A), the weight may be set to a value greater than 1, which is 1.5, judging that the difference between the temperature during the read operation and the temperature during the program operation is relatively increased.

When the internal temperature RT measured during the read operation and the internal temperature PT measured during the program operation are both less than or equal to the first set temperature A (RT≤A, PT≤A), the weight may be set to 2, judging that the difference between the temperature during the read operation and the temperature during the program operation is relatively small, but the temperature during the read operation is relatively low.

When the internal temperature RT measured during the read operation is less than or equal to the first set temperature A (RT≤A) and the internal temperature PT measured during the program operation is within the set temperature range (A<PT≤B), the weight may be set to 3, judging that the temperature during the read operation is relatively low and the difference between the temperature during the read operation and the temperature during the program operation is relatively large.

When the internal temperature RT measured during the read operation is less than or equal to the first set temperature A (RT≤A) and the internal temperature PT measured during the program operation exceeds the second set temperature B (B<PT), the weight may be set to 4, judging that the temperature during the read operation is relatively low and the difference between the temperature during the read operation and the temperature during the program operation is relatively the largest.

When the internal temperature RT measured during the read operation and the internal temperature PT measured during the program operation both exceed the second set temperature B (B<RT, B<PT), the weight may be set to 2, judging that the difference between the temperature during the read operation and the temperature during the program operation is relatively small, but the temperature during the program operation is relatively high.

When the internal temperature RT measured during the read operation exceeds the second set temperature B (B<RT) and the internal temperature PT measured during the program operation is within the set temperature range (A<PT≤B), the weight may be set to 1.5, judging that the difference between the temperature during the read operation and the temperature during the program operation is relatively large.

When the internal temperature RT measured during the read operation exceeds the second set temperature B (B<RT) and the internal temperature PT measured during the program operation is less than or equal to the first set temperature A (PT≤A), the weight may be set to 2, judging that the difference between the temperature during the read operation and the temperature during the program operation is relatively the largest.

The method of setting the weight described above is not limited to the embodiments described above. In one embodiment, the weight may be set to increase as the internal temperature measured during the read operation is relatively low. In another embodiment, as the temperature difference between the internal temperature measured during the read operation and the internal temperature measured during the program operation increases, the magnitude of the increment in value of the weight may be adjusted.

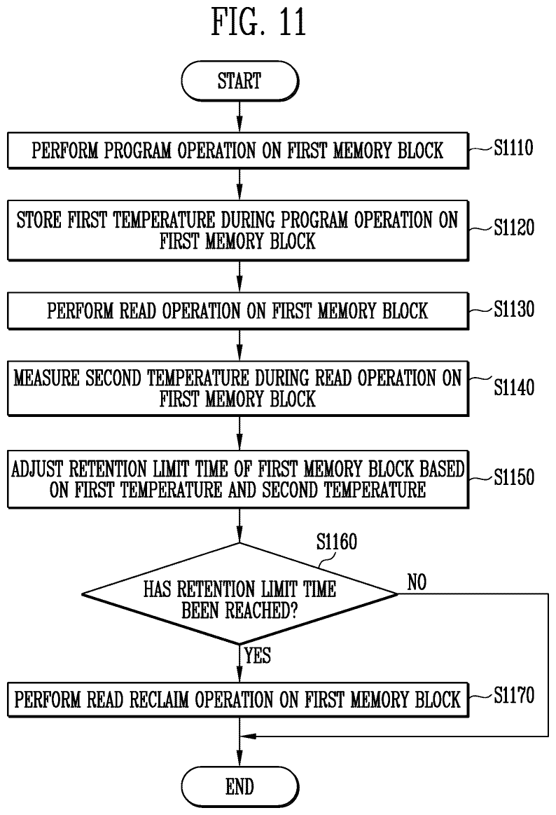

FIG. 11 is a flowchart illustrating a method of operating a semiconductor memory device according to another embodiment of the present disclosure. The method may be performed by elements of the semiconductor memory device 100 shown in FIGS. 1 to 7.

Referring to FIGS. 1 to 7 and FIG. 11, a method of operating the semiconductor memory device according to another embodiment of the present disclosure will be described as follows.

At S1110, the semiconductor memory device 100 performs a program operation on a selected memory block, such as the first memory block BLK1. For example, the semiconductor memory device 100 may receive, from an external device, a program command CMD corresponding to the first memory block BLK1 and the data DATA to be programmed. The semiconductor memory device 100 may receive an address corresponding to the first memory block BLK1 from the external device together with the program command CMD and the data DATA. The semiconductor memory device 100 may perform the program operation in accordance with the program command CMD to store the data DATA in the first memory block BLK1.

The temperature measurement circuit 180 may measure an internal temperature of the semiconductor memory device 100 during the program operation on the first memory block BLK1.

At S1120, the temperature measurement circuit 180 may generate and output the program operation temperature code temp_code_P corresponding to the internal temperature of the semiconductor memory device 100 measured during the program operation on the first memory block BLK1, that is, a first temperature. The block retention determiner 173 of the retention characteristic determiner 170 may receive and store the program operation temperature code temp_code_P. That is, the block retention determiner 173 may store the first temperature, which is the internal temperature of the semiconductor memory device 100, during the program operation of the first memory block BLK1.

At S1130, the semiconductor memory device 100 performs a read operation on the first memory block BLK1. For example, the semiconductor memory device 100 may receive a read command CMD corresponding to the first memory block BLK1 and an address corresponding to the first memory block BLK1 from the external device. The semiconductor memory device 100 may perform the read operation on the first memory block BLK1 in accordance with the read command CMD.

At S1140, the temperature measurement circuit 180 may measure an internal temperature of the semiconductor memory device 100 during the read operation on the first memory block BLK1, that is, a second temperature. For example, the temperature measurement circuit 180 may generate and output the read operation temperature code temp_code_R corresponding to the internal temperature of the semiconductor memory device 100 measured during the read operation on the first memory block BLK1, that is, the second temperature.

At S1150, the block retention determiner 173 may adjust a retention limit time of the first memory block BLK1 based on the first temperature and the second temperature.

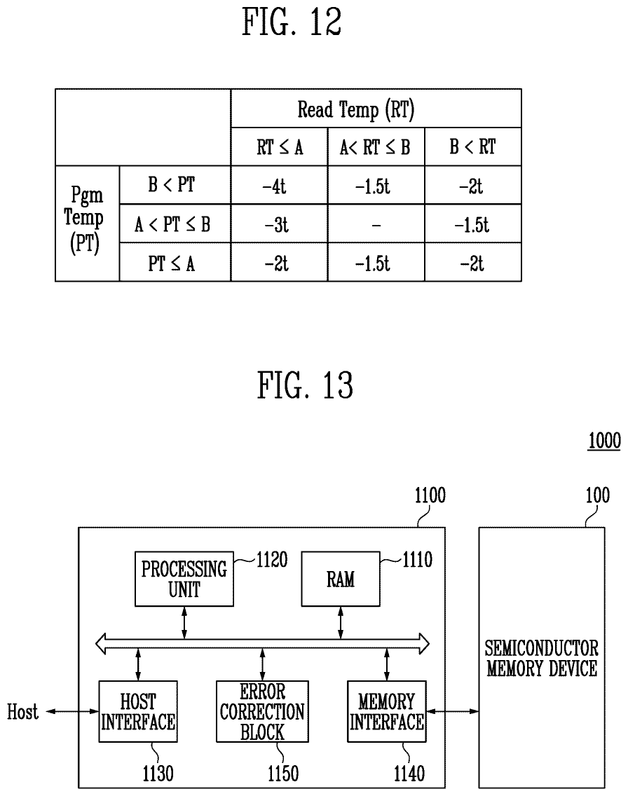

For example, the retention limit time of the first memory block BLK1 may be maintained or shortened based on the program operation temperature code temp_code_P previously stored and corresponding to the first memory block BLK1, and the read operation temperature code temp_code_R received from the temperature measurement circuit 180. For example, the block retention determiner 173 may calculate the temperature difference between the first temperature corresponding to the program operation temperature code temp_code_P and the second temperature corresponding to the read operation temperature code temp_code_R. The block retention determiner 173 may set a reduction time of the retention limit time based on the calculated temperature difference and the second temperature. The block retention determiner 173 may adjust the retention limit time of the first memory block BLK1 by subtracting the set reduction time from the retention limit time after the read operation on the first memory block BLK1 is completed from the retention limit time of the first memory block BLK1. For example, the block retention determiner 173 may set to increase the reduction time when the calculated temperature difference is relatively large, and to increase the reduction time when the second temperature is relatively low. The method of setting the reduction time will be described in detail below with reference to FIG. 12.

At S1160, the block retention determiner 173 receives the time information T_inf about the elapsed time since the program operation on the first memory block BLK1 is performed. Further, the block retention determiner 173 determines whether the first memory block BLK1 has reached the retention limit time based on the received time information T_inf.

Further, the block retention determiner 173 may receive the time information T_inf about the elapsed time since the program operation is performed on each of memory blocks on which the program operation was performed, and detect a memory block which has reached the retention limit time among the memory blocks.

When it is determined at S1160 that the first memory block BLK1 reaches the retention limit time (Yes), a read reclaim operation on the first memory block BLK1 may be performed at S1170.

For example, when the first memory block BLK1 reaches the retention limit time, the block retention determiner 173 generates the read reclaim control signal reclaim_ctr to perform the read reclaim operation on the first memory block BLK1. The control logic 140 may control the address decoder 120, the read and write circuit 130, and the voltage generator 150 to perform the read reclaim operation on the first memory block BLK1 in response to the read reclaim control signal reclaim_ctr. The address decoder 120, the read and write circuit 130, and the voltage generator 150 may read valid data stored in the first memory block BLK1 during the read reclaim operation, and program the read data into a new memory block.

When a memory block which has reached the retention limit time is detected among the memory blocks on which the program operation is performed at S1160 described above, the read reclaim operation on the detected memory block may be performed at S1170.

At S1160, when it is determined that the first memory block BLK1 has not reached the retention limit time (No), an operation of the semiconductor memory device 100 may be ended.

FIG. 12 is a diagram illustrating a method of adjusting a retention limit time of a memory block based on an internal temperature during a program operation and an internal temperature during a read operation according to an embodiment of the present disclosure.

Referring to FIG. 12, a reduction time may increase when the internal temperature (i.e., Read Temp; RT) measured during the read operation is relatively low, and the reduction time may increase when the difference between the internal temperature (i.e., Pgm Temp; PT) measured during the program operation and the internal temperature RT measured during the read operation increases.

For example, when the internal temperature RT measured during the read operation and the internal temperature PT measured during the program operation both fall within the set temperature range, i.e., the temperature range which exceeds the first set temperature A and is below or equal to the second set temperature B (A<RT≤B, A<PT≤B), the reduction time may be set to 0. Accordingly, the retention limit time of a corresponding memory block maintains an initial set time.

When the internal temperature RT measured during the read operation is within the set temperature range (A<RT≤B), and the internal temperature PT measured during the program operation exceeds the second set temperature B (B<PT) or is less than or equal to the first set temperature A (PT≤A), the reduction time is set to 1.5 t, judging that the difference between the temperature during the read operation and the temperature during the program operation is relatively increased. Accordingly, the retention limit time of the corresponding memory block may be shortened by the set reduction time (i.e., 1.5 t) from the initial set time. In some embodiments, t may be a base unit time.

When the internal temperature RT measured during the read operation and the internal temperature PT measured during the program operation are both less than or equal to the first set temperature A (RT≤A, PT≤A), the reduction time is set to 2 t, judging that the difference between the temperature during the read operation and the temperature during the program operation is relatively small, but the temperature during the read operation is determined to be relatively low. Accordingly, the retention limit time of the corresponding memory block may be shortened by the set reduction time (i.e., 2 t) from the initial set time.

When the internal temperature RT measured during the read operation is less than or equal to the first set temperature A (RT≤A) and the internal temperature PT measured during the program operation is within the set temperature range (A<PT≤B), the reduction time is set to 3 t, judging that the temperature during the read operation is relatively low and the temperature difference between the temperature during the read operation and the temperature during the program operation is relatively large. Accordingly, the retention limit time of the corresponding memory block may be shortened by the set reduction time (i.e., 3 t) from the initial set time.

When the internal temperature RT measured during the read operation is less than or equal to the first set temperature A (RT≤A), and the internal temperature PT measured during the program operation exceeds the second set temperature B (B<PT), the reduction time is set to 4 t, judging that the temperature during the read operation is relatively low, and the difference between the temperature during the read operation and the temperature during the program operation is relatively the largest. Accordingly, the retention limit time of the corresponding memory block may be shortened by the set reduction time (i.e., 4 t) from the initial set time.

When the internal temperature RT measured during the read operation and the internal temperature PT measured during the program operation both exceed the second set temperature B (B<RT, B<PT), the reduction time is set to 2 t, judging that the difference between the temperature during the read operation and the temperature during the program operation is relatively small, but the temperature during the program operation is relatively high. Accordingly, the retention limit time of the corresponding memory block may be shortened by the set reduction time (i.e., 2 t) from the initial set time.

When the internal temperature RT measured during the read operation exceeds the second set temperature B (B<RT) and the internal temperature PT measured during the program operation is within the set temperature range (A<PT≤B), the reduction time is set to 1.5 t, judging that the difference between the temperature during the read operation and the temperature during the program operation is relatively large. Therefore, the retention limit time of the corresponding memory block may be shortened by the set reduction time (i.e., 1.5 t) from the initial set time.

When the internal temperature RT measured during the read operation exceeds the second set temperature B (B<RT) and the internal temperature PT measured during the program operation is below or equal to the first set temperature A (PT≤A), the reduction time is set to 2 t, judging that the difference between the temperature during the read operation and the temperature during the program operation is relatively the largest. Accordingly, the retention limit time of the corresponding memory block may be shortened by the set reduction time (i.e., 2 t) from the initial set time.

The method of setting the reduction time described above is not limited to the embodiments described above. In one embodiment, the reduction time may be set to increase as the internal temperature measured during the read operation is relatively low. In another embodiment, as the temperature difference between the internal temperature measured during the read operation and the internal temperature measured during the program operation increases, and the increment in reduction time may be adjusted.

FIG. 13 is a block diagram illustrating a memory system 1000 including the semiconductor memory device 100 of FIG. 1.

Referring to FIG. 13, the memory system 1000 includes the semiconductor memory device 100 and a controller 1100. The semiconductor memory device 100 may be the semiconductor memory device 100 described above with reference to FIG. 1. Hereinafter, any repetitive detailed descriptions already mentioned above are omitted.

The controller 1100 is connected to a host Host and the semiconductor memory device 100. In response to a request from the host Host, the controller 1100 is configured to access the semiconductor memory device 100. For example, the controller 1100 is configured to control read, write, erase, and background operations of the semiconductor memory device 100. The controller 1100 is configured to provide an interface between the semiconductor memory device 100 and the host Host. The controller 1100 is configured to drive firmware for controlling the semiconductor memory device 100.

The controller 1100 includes Random-Access Memory (RAM) 1110, a processing unit 1120, a host interface 1130, a memory interface 1140, and an error correction block 1150. The RAM 1110 is used as at least one of operational memory of the processing unit 1120, cache memory between the semiconductor memory device 100 and the host Host, or buffer memory between the semiconductor memory device 100 and the host Host. The processing unit 1120 controls various operations of the controller 1100. In addition, the controller 1100 may temporarily store program data provided from the host Host during a write operation.

The host interface 1130 includes protocols for performing data exchange between the host Host and the controller 1100. In an embodiment, the controller 1100 is configured to communicate with the host Host through at least one of various communication standards or interfaces such as a Universal Serial Bus (USB) protocol, a Multi-Media Card (MMC) protocol, a Peripheral Component Interconnect (PCI) protocol, a PCI-Express (PCI-e or PCIe) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, a private protocol, and the like.

The memory interface 1140 interfaces with the semiconductor memory device 100. For example, the memory interface includes a NAND interface or a NOR interface.

The error correction block 1150 is configured to detect and correct errors in data received from the semiconductor memory device 100 using an error correcting code (ECC). The processing unit 1120 may adjust a read voltage according to the error detection result of the error correction block 1150, and control the semiconductor memory device 100 to re-perform a read operation using the adjusted read voltage. In an embodiment, an error correction block may be provided as a component of the controller 1100.

The controller 1100 and the semiconductor memory device 100 may be integrated into a single semiconductor device. In an embodiment, the controller 1100 and the semiconductor memory device 100 may be integrated into a single semiconductor device to form a memory card. For example, the controller 1100 and the semiconductor memory device 100 may be integrated into a single semiconductor device to form a memory card, such as a Personal Computer Memory Card International Association (PCMCIA), a Compact Flash (CF) card, a smart media card (SM, SMC), a memory stick, a multimedia card (MMC, RS-MMC, MMCmicro), an SD card (SD, miniSD, microSD, SDHC), Universal Flash Storage (UFS), or the like.

The controller 1100 and the semiconductor memory device 100 may be integrated into a single semiconductor device to form a Solid-State Drive (SSD). The SSD includes a storage device configured to store data in semiconductor memory. When the memory system 1000 is used as an SSD, the operation speed of the host Host connected to the memory system 1000 is dramatically improved.

In other embodiments, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smartphone, an e-book, a Portable Multimedia Player (PMP), a portable game console, a navigation device, a black box, a digital camera, a three-dimensional television, a digital audio recorder, a digital audio player, a digital picture recorder, a digital picture player, a digital video recorder, a digital video player, digital video player, a device capable of transmitting or receiving information in a wireless environment, one of various electronic devices forming a home network, one of various electronic devices forming a computer network, one of various electronic devices forming a telematics network, an RFID device, or one of various components forming a computing system, and the like.

In an embodiment, the semiconductor memory device 100 or the memory system 1000 may be mounted in various types of packages. For example, the semiconductor memory device 100 or the memory system 1000 may be mounted in various types of packages, such as Package on Package (PoP), Ball grid arrays (BGAs), Chip Scale Packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi-Chip Package (MCP), Wafer-level Fabricated Package (WFP), Wafer-Level Processed Stack Package (WSP), or the like.

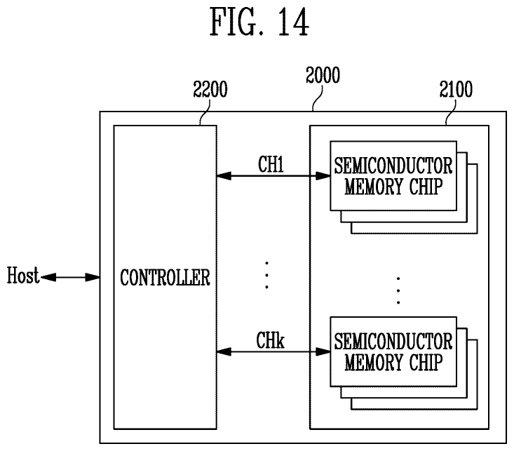

FIG. 14 is a block diagram illustrating an application example 2000 of the memory system 1000 of FIG. 13.

Referring to FIG. 14, the memory system 2000 includes a semiconductor memory device 2100 and a controller 2200. The semiconductor memory device 2100 includes a plurality of semiconductor memory chips. The plurality of semiconductor memory chips is divided into a plurality of groups.

FIG. 14 illustrates that the plurality of groups communicate with the controller 2200 via first to kth channels CH1 to CHk, respectively. Each semiconductor memory chip may be configured and operate similarly to the semiconductor memory device 100 described above with reference to FIG. 1.

Each group is configured to communicate with the controller 2200 through one common channel. The controller 2200 is configured similarly to the controller 1100 described with reference to FIG. 13, and is configured to control the plurality of semiconductor memory chips of the semiconductor memory device 2100 through the plurality of channels CH1 to CHk.

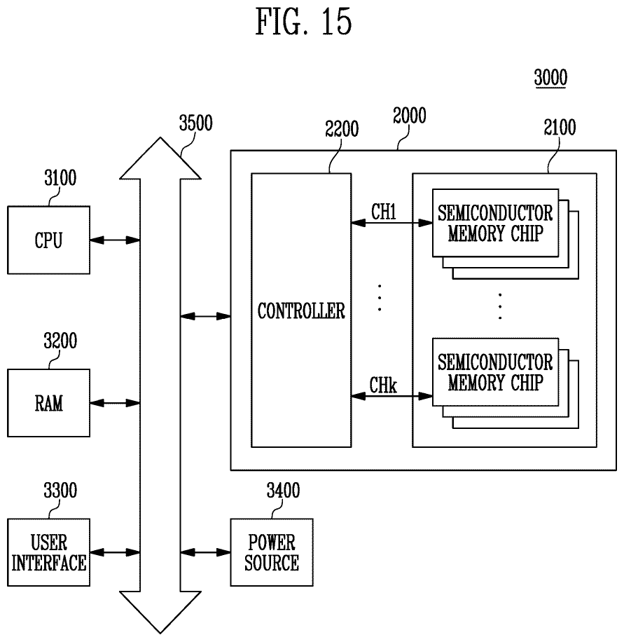

FIG. 15 is a block diagram illustrating a computing system 3000 including the memory system 2000 described with reference to FIG. 14.

Referring to FIG. 15, the computing system 3000 includes a central processing unit (CPU) 3100, Random-Access Memory (RAM) 3200, a user interface 3300, a power source 3400, a system bus 3500, and the memory system 2000.

The memory system 2000 is electrically connected to the central processing unit 3100, the RAM 3200, the user interface 3300, and the power source 3400 via the system bus 3500. Data provided via the user interface 3300 or processed by the central processing unit 3100 is stored in the memory system 2000.

In FIG. 15, the semiconductor memory device 2100 is illustrated as being connected to the system bus 3500 via the controller 2200. However, the semiconductor memory device 2100 may be configured to be directly connected to the system bus 3500. When the semiconductor memory device 2100 is directly connected to the system bus 3500, the functions of the controller 2200 may be performed by the central processing unit 3100 and the RAM 3200.

FIG. 15 illustrates that the memory system 2000 described with reference to FIG. 14 is provided. However, the memory system 2000 may be replaced by the memory system 1000 described with reference to FIG. 13. In an embodiment, the computing system 3000 may be configured to include both the memory systems 1000 and 2000 described with reference to FIGS. 13 and 14, respectively.

According to some embodiments of the present disclosure, the reliability of a semiconductor memory device may be improved by adjusting a read count increment based on an internal temperature during a program operation and an internal temperature during a read operation. Further, the reliability of the semiconductor memory device may be improved by adjusting a retention limit time of a memory block based on the internal temperature during the program operation and the internal temperature during the read operation.

The embodiments of the present disclosure disclosed herein and in the drawings are provided by way of illustration only to facilitate the technical features of the present disclosure and to aid in understanding the present disclosure, and are not intended to limit the scope of the present disclosure. It will be apparent to those skilled in the art to which the present disclosure pertains that other modifications based on the technical scope of the present disclosure may be practiced in addition to the embodiments disclosed herein. Furthermore, the embodiments may be combined to form additional embodiments.

What is claimed is:

1. A semiconductor memory device comprising:
a memory cell array including a plurality of memory blocks;
a peripheral circuit performing a program operation or a read operation on a selected memory block from among the plurality of memory blocks;
a temperature measurement circuit performing a temperature measurement operation to measure a first temperature during the program operation and a second temperature during the read operation; and
a block read counter deriving a read count increment of the selected memory block based on the first temperature and the second temperature and updating a read count value of the selected memory block based on the read count value and the derived read count increment.

2. The semiconductor memory device of claim 1, wherein the block read counter calculates a temperature difference between the first temperature and the second temperature, and derives the read count increment based on the calculated temperature difference and the second temperature.

3. The semiconductor memory device of claim 2, wherein the block read counter derives the read count increment by increasing the read count increment as the temperature difference increases, and increasing the read count increment as the second temperature decreases.

4. The semiconductor memory device of claim 1, wherein the temperature measurement circuit measures the first temperature and outputs the first temperature as a program operation temperature code, and measures the second temperature and outputs the second temperature as a read operation temperature code.

5. The semiconductor memory device of claim 4, wherein the block read counter comprises:
temperature code storage receiving the program operation temperature code from the temperature measurement circuit and storing the program operation temperature code;
a read count compensator calculating a temperature difference between the first temperature and the second temperature based on the program operation temperature code stored in the temperature code storage and the read operation temperature code received from the temperature measurement circuit, and deriving the read count increment based on the calculated temperature difference and a temperature corresponding to the read operation temperature code; and
read count storage updating and storing the read count value of the selected memory block based on the read count increment.

6. The semiconductor memory device of claim 1, further comprising control logic controlling the peripheral circuit,
wherein the control logic determines whether to perform a read reclaim operation on the selected memory block based on the read count value for the selected memory block.

7. The semiconductor memory device of claim 1, further comprising a retention characteristic determiner managing a retention limit time for the selected memory block among the plurality of memory blocks.

8. The semiconductor memory device of claim 7, wherein the retention characteristic determiner adjusts the retention limit time of the selected memory block based on the first temperature and the second temperature.

9. The semiconductor memory device of claim 8, wherein the retention characteristic determiner calculates a temperature difference between the first temperature and the second temperature, and sets the retention limit time of the selected memory block to be maintained or shortened by a reduction time, based on the calculated temperature difference and the second temperature.

10. The semiconductor memory device of claim 9, wherein the retention characteristic determiner sets the retention limit time to decrease as the temperature difference increases, and to decrease as the second temperature decreases.

11. The semiconductor memory device of claim 10, wherein the retention characteristic determiner comprises:
a timer measuring an elapsed time after the program operation on each of the plurality of memory blocks to output time information; and
a block retention determiner managing the retention limit time of each of the plurality of memory blocks, and detecting a memory block, of which the elapsed time after the program operation reaches the retention limit time, based on the time information, to generate a read reclaim control signal for the detected memory block.

12. A method of operating a semiconductor memory device, the method comprising:
performing a program operation on a selected memory block among a plurality of memory blocks, and measuring a first temperature during the program operation;
performing a read operation on the selected memory block, and measuring a second temperature during the read operation;
deriving a read count increment of the selected memory block based on the measured first and second temperatures; and
updating a read count value of the selected memory block based on the read count value and the read count increment.

13. The method of claim 12, wherein deriving the read count increment comprises:
calculating a temperature difference between the first temperature and the second temperature; and
deriving the read count increment based on the calculated temperature difference and the second temperature.

14. The method of claim 13, wherein deriving the read count increment includes deriving the read count increment by increasing the read count increment as the temperature difference increases, and increasing the read count increment as the second temperature decreases.

15. The method of claim 12, further comprising determining whether to perform a read reclaim operation on the selected memory block based on the read count value for the selected memory block.

16. A method of operating a semiconductor memory device, the method comprising:
performing a program operation on a selected memory block among a plurality of memory blocks, and measuring a first temperature during the program operation;
performing a read operation on the selected memory block, and measuring a second temperature during the read operation; and
adjusting a retention limit time of the selected memory block based on the measured first and second temperatures.

17. The method of claim 16, further comprising:
measuring an elapsed time after the program operation on the selected memory block; and
performing a read reclaim operation on the selected memory block based on the measured elapsed time and the retention limit time.

18. The method of claim 16, wherein adjusting the retention limit time of the selected memory block comprises:
calculating a temperature difference between the first temperature and the second temperature; and
setting the retention limit time to be maintained or shortened by a reduction time, based on the calculated temperature difference and the second temperature.

19. The method of claim 18, wherein, as the temperature difference increases, the retention limit time decreases by increasing the reduction time, and as the second temperature decreases, the retention limit time decreases by increasing the reduction time.

20. The method of claim 17, wherein performing the read reclaim operation includes performing the read reclaim operation on the selected memory block when the measured elapsed time after the program operation reaches the retention limit time.
